(19) United States
(12) Patent Application Publication
(10) Pub. No.: US 2009/0073063 A1
(43) Pub. Date: Mar. 19, 2009

(54) METHOD AND APPARATUS FOR POLARIZATION DISPLAY OF ANTENNA

(75) Inventors: Yong Liu, Shanghai (CN); Kairaz S. Contractor, Shanghai (CN); Yun Yuan, Shanghai (CN)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: NXP B.V., Eindhoven (NL)

(21) Appl. No.: 12/067,892

(22) PCT Filed: Sep. 14, 2006
(86) PCT No.: PCT/IB2006/053272

§ 371 Date: Oct. 24, 2008

(30) Foreign Application Priority Data
Sep. 23, 2005 (CN) 200510106902.4

(51) Int. Cl. G01R 29/10

(52) U.S. Cl. 343/703

(57) ABSTRACT

The invention discloses a method and apparatus for polarization display of antenna. The apparatus for polarization display of antenna comprises a selecting means for selecting a plurality of predetermined radiation directions from radiation directions of an antenna, a mapping means for mapping the plurality of predetermined radiation directions into a coordinates chart, an obtaining means for obtaining corresponding radiation data for the antenna in the plurality of predetermined radiation directions, and a plotting means for plotting a polarization pattern of the antenna in the plurality of predetermined radiation directions on the coordinates chart, according to the radiation data. With the method and apparatus of the invention, all polarization information of the antenna in each radiation direction can be provided with only one FIGURE.

### FIELD OF THE INVENTION

The present invention relates generally to antenna techniques, and more particularly, to a method and apparatus for polarization display of antenna.

### BACKGROUND OF THE INVENTION

Antenna is a radio device used mainly in communication field, with a function to implement transmission and reception of electromagnetic waves in the air. Any electromagnetic wave transmitted by an antenna comprises an electric vector field and a magnetic vector field, which are always orthogonal to each another and are orthogonal to the radiation direction of the electromagnetic wave in the radiation far field. When the antenna transmits the electromagnetic wave, the directions of the electric field vector and the magnetic field vector vary periodically with time in each radiation direction, which is commonly referred to antenna polarization.

To test whether the radiation characteristics of an antenna satisfies various requirements, it's necessary to research the polarization of the antenna during development and design of the antenna, generally by placing the antenna in a spherical coordinates system for observation. Referring to FIG. 1, the spherical coordinates system is placed as such for ease of illustration, where the Z-axis is located in the paper surface and extends upwardly along a vertical direction, the Y-axis is orthogonal to the Z-axis and extends rightward in the paper surface, and the X-axis is orthogonal to the paper surface. For any radiation direction (θ, φ) of the antenna, θ represents the angle formed by the radiation direction and the positive direction of the Z-axis in the spherical coordinates system, and φ represents the angle formed by the positive direction of the X-axis and the projection of the radiation direction on the X-Y plane in the spherical coordinates system.

The electric field vector of an electromagnetic wave in the radiation far field is composed of two linear polarization components E_{θ} and E_{φ}, which are orthogonal to each other. A local plane rectangular coordinates system is formed by taking the direction of E_{θ} as the vertical axis and the direction of E_{φ} as the horizontal axis. The coordinates plane is orthogonal to the radiation direction (θ, φ). If the electric field vector is mapped into the local plane rectangular coordinates system according to the variations of E_{θ} and E_{φ} at any moment in one time cycle, the end point of the electric field vector varies with time and rotates around the origin of the local plane rectangular coordinates system. Accordingly, its rotation trace will plot a closed pattern, which depicts the polarization characteristics of the antenna in the direction (θ, φ). This pattern is referred to as the polarization pattern of antenna. The rotation is classified as left-hand and right-hand, resulting that the polarization is also classified as left-hand and right-hand.

Usually, the polarization pattern of the antenna is an ellipse and correspondingly the polarization is referred to as an elliptical polarization. The elliptical polarization may be left-hand or right-hand elliptical polarization according to the rotation direction of the trace of the end points of the electric field vector. An ellipse has a major axis and a minor one. The axis ratio (AR) is generally defined as the ratio of the major axis to the minor axis, and polarization ellipses with different shapes have different AR values. The major axis and the minor axis are generally not superposed on the local plane rectangular coordinates system. In this case, the included angle between the major axis of the ellipse and the positive direction of the vertical axis E_{θ} in the local plane rectangular coordinates system is called as a tilt angle of the elliptical polarization in the radiation direction.

When the two linear components E_{θ} and E_{φ} of the electric field vector have the same amplitude but have phase difference of +90 or −90 degree, the polarization pattern of the antenna is a circle and the corresponding polarization is called as a circular polarization. The circular polarization may be left-hand or right-hand circular polarization, depending on whether the rotation direction of the electric field vector is left-hand or right-hand. Since the major axis and the minor axis of the circle are equal, the AR value of the circular polarization is 1 or 0 dB.

When one of the two linear components E_{θ} and E_{φ} of the electric field has an amplitude of 0 or the two components have equal phase, the polarization pattern for the antenna is a line segment, and the corresponding polarization is linear polarization. Since the minor axis of the line segment is 0, the AR value of the linear polarization is infinite. The included angle between the line segment and the positive direction of the vertical axis E_{θ} of the local plane rectangular coordinates system is the tilt angle of the linear polarization in the radiation direction. When the tilt angle is 0 degree, the corresponding polarization is vertically linear polarization. When the tilt angle is 90 degree, the corresponding polarization is horizontally linear polarization.

When researching the polarization characteristics of the antenna, it's necessary to know the polarization type (elliptical, circular or linear polarization) for the observed radiation direction. When the elliptical polarization is determined, we further need to know the rotation direction (left-hand or right-hand polarization), the tilt angle and the AR value. When the circular polarization is determined, we further need to know the rotation direction (left-hand or right-hand polarization) of the circular polarization. Even when it's linear polarization, we further need to know the tilt angle of the linear polarization. Generally speaking, the polarization state of the antenna in the radiation direction can be known based on the above polarization information in the observed radiation direction.

In prior arts, Poincaré sphere is often used to record the polarization information of the antenna in a given radiation direction. The Poincaré sphere can distinguish polarization states with different tilt angles and AR values, but it can't represent information reflecting how the polarization characteristics of the antenna vary with the radiation direction. With a method proposed by Wolfgang-Martin Boerner, Wei-Ling Yan, An-Qing Xi and Yoshio Yamaguchi in “On the basic principles of radar polarimetry the target characteristic polarization state theory of Kennaugh, Huynen's polarization fork concept, and its extension to the partially polarized case”, Proceeding of the IEEE Vol. 79, No. 10 Oct. 1991, the surface of the Poincaré sphere is projected onto a complex plane, so that the entire surface of the sphere could be displayed and mapped onto the plane. With another method proposed by Harry Mieras in “Optimal polarizations of simple compound targets”, IEEE Transactions on Antennas and Propagation, Vol. 31, No. 6, November 1983, pp. 996-999, an equal area projection of the Poincaré sphere is used to display polarization. Georges A. Deschamps and P. Edward Mast improved the Poincaré sphere representation by introducing a plurality of points inside the sphere to represent partially polarized states, as described in “Poincaré sphere representation of partially polarized fields”, IEEE Transactions on Antennas and Propagation, Vol. 21, No. 4, July 1973, pp. 474-478. With a method proposed by George H. Knittle in “The polarization sphere as a graphical aid in determining the polarization of an antenna by amplitude measurements only”, IEEE Transactions on Antennas and Propagation, Vol. 15, No. 2, March 1967, pp. 217-221, a plurality of polarization charts are introduced, which are the stereographic projections of the Poincaré sphere.

While the above methods extended and improved the representation capability of the Poincaré sphere and enabled it to be incorporated into experimental and measurement methods, they are not capable of providing complete polarization information and some of these display methods make it inconvenient to represent the results on the print media lucidly and in one FIGURE.

### OBJECT AND SUMMARY OF THE INVENTION

An object of the present invention is to provide a method and apparatus for polarization display of antenna, which allows to provide complete polarization information for the antenna in each radiation direction.

Another object of the invention is to provide a method and apparatus for polarization display of antenna, which allows to provide complete polarization information for the antenna in each radiation direction with only one FIGURE.

To fulfill the above objects of the invention, a method for polarization display of antenna is provided in accordance with the invention, comprising steps of:

(a) selecting a plurality of predetermined radiation directions from radiation directions of an antenna;

(b) mapping the plurality of predetermined radiation directions into a coordinates chart;

(c) obtaining corresponding radiation data for the antenna in the plurality of predetermined radiation directions; and

(d) plotting a polarization pattern of the antenna in the plurality of predetermined radiation directions on the coordinates chart, according to the radiation data.

To fulfill the above objects of the invention, an apparatus for polarization display of antenna is provided in accordance with the invention, comprising:

a selecting means, for selecting a plurality of predetermined radiation directions from radiation directions of the antenna;

a mapping means, for mapping the plurality of predetermined radiation directions into a coordinates chart;

a obtaining means, for obtaining corresponding radiation data for the antenna in the plurality of predetermined radiation directions; and

a plotting means, for plotting a polarization pattern of the antenna in the plurality of predetermined radiation directions on the coordinates chart, according to the radiation data.

Other objects and attainments together with a fuller understanding of the invention will become apparent and appreciated by referring to the following descriptions and claims taken in conjunction with the accompanying drawings.

### BRIEF DESCRIPTION OF THE DRAWINGS

FIG. 1 illustrates a location relationship of a radiation direction (θ, φ) in a spherical coordinates system;

FIG. 2 illustrates a time-domain waveform and a corresponding polarization pattern for two electric field components E_{θ} and E_{φ} of an antenna in a given radiation direction (θ, φ);

FIG. 3 illustrates a two-dimension planar rectangular chart for representing a complete polarization information of an antenna in accordance with the invention;

FIG. 4 illustrates a structure of a dipole antenna with linear polarization characteristics;

FIG. 5 illustrates a three-dimension radiation pattern of the dipole antenna shown in FIG. 4;

FIG. 6 illustrates the display results for the complete polarization characteristics of the dipole antenna of FIG. 4 in the two-dimension planar rectangle chart in accordance with the invention;

FIG. 7 illustrates a structure of a patch antenna with circular polarization characteristics;

FIG. 8 illustrates a three-dimension radiation pattern of the patch antenna of FIG. 7;

FIG. 9 illustrates the display results of the complete polarization characteristics of the patch antenna of FIG. 7 in the two-dimension planar rectangle chart in accordance with the invention;

FIG. 10 illustrates a structure of a Planar Inverted-F Antenna (PIFA) with complicated polarization characteristics;

FIG. 11 illustrates a three-dimension radiation pattern of the PIFA of FIG. 10;

FIG. 12 illustrates the display results of the complete polarization characteristics of the PIFA of FIG. 10 in the two-dimension planar rectangle chart in accordance with the invention;

FIG. 13 illustrates the display results of the complete polarization characteristics of the dipole antenna on a spherical chart in accordance with another embodiment of the invention;

FIG. 14 illustrates the display results of the complete polarization characteristics of the patch antenna on the spherical chart in accordance with another embodiment of the invention;

FIG. 15 illustrates the display results of the complete polarization characteristics of the PIFA on the spherical chart in accordance with another embodiment of the invention; and

FIG. 16 illustrates the functional modules corresponding to the method for polarization display of antenna in accordance with the invention.

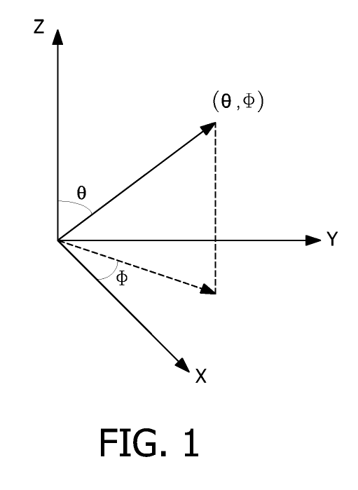

Throughout all the above drawings, same reference numerals will be understood to refer to similar or corresponding features or functions.

### DETAILED DESCRIPTION OF THE INVENTION

According to the method for polarization display of antenna as proposed by the invention, a plurality of radiation directions are selected as sample directions from the antenna's radiation directions, and the electric far field data is obtained for each sample direction. Then the selected sample directions are mapped into a plurality of corresponding map points on a two-dimension planar rectangular chart or a spherical chart. Afterwards, according to the electric far field data in each sample direction, the polarization pattern of the radiated far field in each sample direction can be plotted, centered at the corresponding map points in the two-dimension planar rectangular chart or the spherical chart. The method for polarization display of antenna according to the invention may be performed solely through a computer software program, or be incorporated into a conventional antenna simulation testing software.

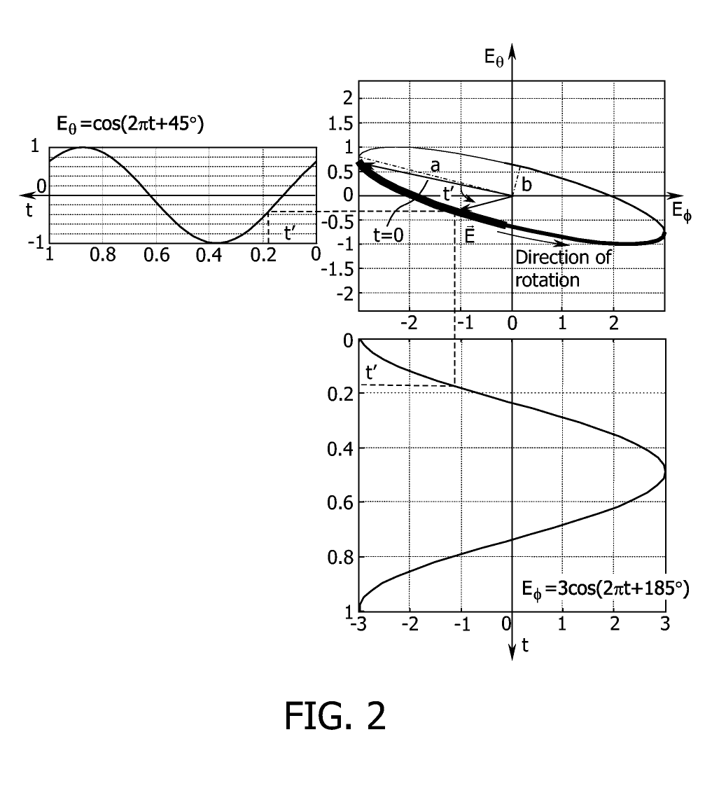

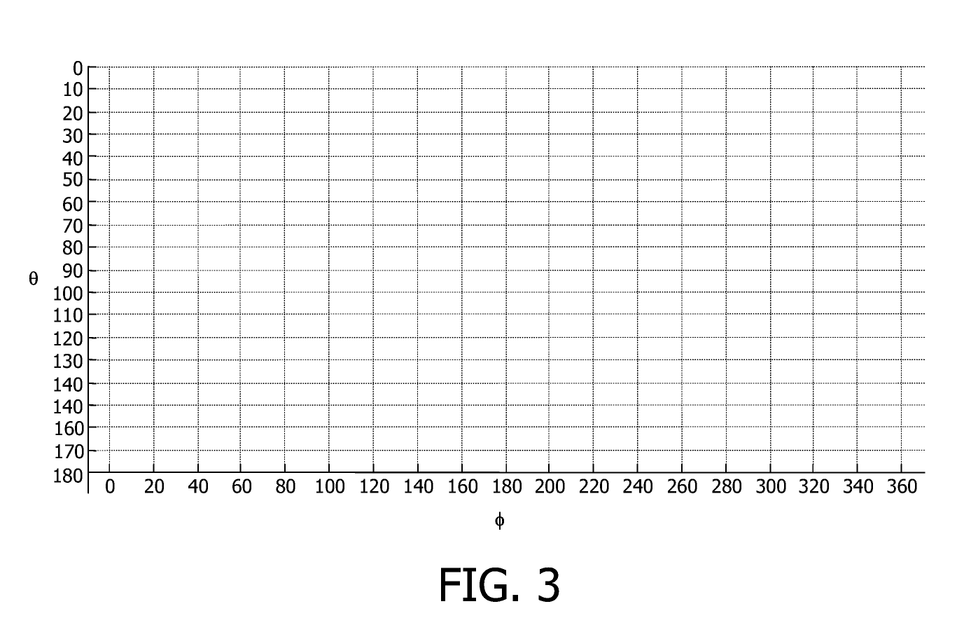

A detailed description will be given to the method for polarization display of antenna according to the invention in conjunction with FIG. 2 and FIG. 3.

As shown in the Background of the Invention, the electric field for an antenna in a radiation direction (θ, φ) is composed of two linear polarization components E_{θ} and E_{φ} which are orthogonal to each other. The trace of the end points of vectors synthesized by the two components in one time cycle is the polarization pattern for the antenna in the radiation direction.

FIG. 2 illustrates the components E_{θ} and E_{φ} of an antenna in a particular radiation direction (θ, φ) and the corresponding polarization pattern. In FIG. 2, a represents the semi-major axis of the polarization ellipse, b represents the semi-minor axis of the polarization ellipse, a/b represents the axial ratio of the polarization ellipse, and the direction in which the trace of the polarization ellipse changes from thick to thin represents the rotation direction of the electric field vector.

Referring to FIG. 2, it can be determined whether the antenna is elliptically, circularly or linearly polarized in the radiation direction (θ, φ) according to whether the shape of the polarization pattern is an ellipse, circle or line segment. It can further be determined whether the polarization sense for the antenna is left-hand or right-hand in the radiation direction (θ, φ) according to whether the direction in which the trace of the polarization ellipse changes from thick to thin is clockwise or counterclockwise. According to the included angle between the semi-major axis a and the positive direction of the vertical axis (the positive direction of E_{θ}, the tilt angle of the polarization of the antenna in the radiation direction (θ, φ) can be determined. According to the size of the polarization pattern, the radiation field intensity of the antenna in the radiation direction (θ, φ) can be determined. Moreover, when the radiation field intensity of the antenna in the radiation direction (θ, φ) is so weak that the polarization pattern is too small for discrimination of the polarization type, the polarization type can be determined with help of displaying the AR value. It can be seen from the above description that complete polarization information of the antenna in any radiation direction can be obtained from the polarization pattern, and with the assistance of the AR value when necessary.

When there is a need to obtain complete polarization information of the antenna in all radiation directions, a plurality of radiation directions are selected as sample directions from all radiation directions of the antenna. Then, the electric far field data in these sample directions, such as the modules and the phases of the components E_{θ} and E_{φ}, is obtained by simulating the antenna using, for example, a simulation software. The sample directions are mapped into the corresponding points on a two-dimension rectangular chart or a spherical chart. Finally, the polarization pattern is plotted in the local plane rectangular coordinates system, centered at the corresponding points in the two-dimension planar rectangle chart or the spherical chart, according to the obtained electric far field data in each sample direction.

FIG. 3 illustrates a two-dimension planar rectangular chart for representing the antenna polarization characteristics in accordance with the invention, wherein the vertical axis is the θ axis ranging from 0 to 180 degree and the horizontal axis is the φ axis ranging from 0 to 360 degree.

Selection of the sample directions can be made according to the practically required display resolution, for example, radiation directions with θ and φ of every other 10 degrees can be selected as the sample directions. When there is a need for sharper display, radiation directions can be selected every other 5 degrees as the sample directions.

After the polarization pattern for the antenna in each sample direction is plotted on the two-dimension planar rectangular chart or the spherical chart by using the above method for polarization display of antenna of the invention, it would be helpful for technicians to determine what type of polarization (elliptical, circular or linear polarization) the antenna shows in any interested radiation directions directly through observation. When the antenna shows the elliptical or circular polarization in the interested radiation directions, it can further be determined whether the polarization sense of the antenna is left-hand or right-hand in the interested radiation directions, according to the direction in which the trace of the polarization pattern changes from thick to thin gradually. When the antenna shows the linear polarization, it can be determined whether the polarization of the antenna is horizontal or vertical polarization in the interested radiation directions, according to the position relationship between the polarization line segment and the coordinates axis. When the antenna is elliptical or linear polarization, the tilt angle for the antenna polarization in the interested radiation directions can be determined according to the included angle between the major axis of the polarization pattern and the coordinates axis. Furthermore, the radiation field intensity for the antenna in the interested radiation directions can be determined according to different sizes of the polarization pattern.

It can be seen from the above description that the invention can provide complete polarization information for the antenna in any radiation direction through the polarization pattern and with only one FIGURE, that is, a two-dimension planar rectangle chart or a spherical chart. The method for polarization display of antenna of the invention is thus suitable for use in various print media.

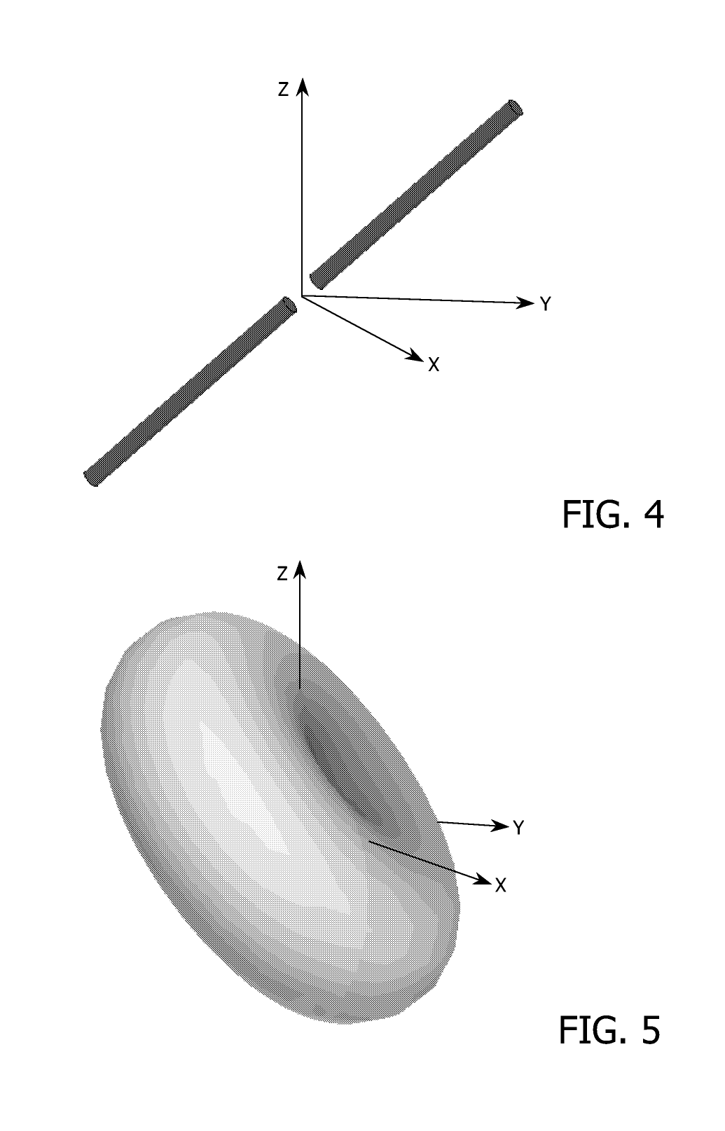

Detailed descriptions will be given below to the method for polarization display of antenna in way of two-dimension plane according to the invention in conjunction with FIGS. 4-12, by taking three well-known antenna structures as examples.

I. Dipole Antenna with the Linear Polarization

FIG. 4 shows a dipole antenna with linear polarization characteristics. As shown in FIG. 4, the dipole antenna is a half wave dipole, with a length of 150 mm and a radius of 1 mm. The dipole antenna has a gap with a width of 2 mm at its center and signals are fed into the dipole antenna through the gap. The resonant frequency of the antenna is 927 MHz. The center of the dipole antenna is located at the origin of the spherical coordinates system and the included angles between the dipole antenna and the three coordinates x, y and z of the coordinates system are all 45 degree.

FIG. 5 illustrates the three-dimension radiation pattern of the dipole antenna obtained by using an existing antenna simulation software. As shown in FIG. 5, this dipole antenna shows a typical donut-shaped radiation pattern of a conventional dipole, that is: the radiation directions along the two length ends of the dipole antenna have the weakest electric field intensity and the radiation directions orthogonal to the antenna have the strongest electric field intensity.

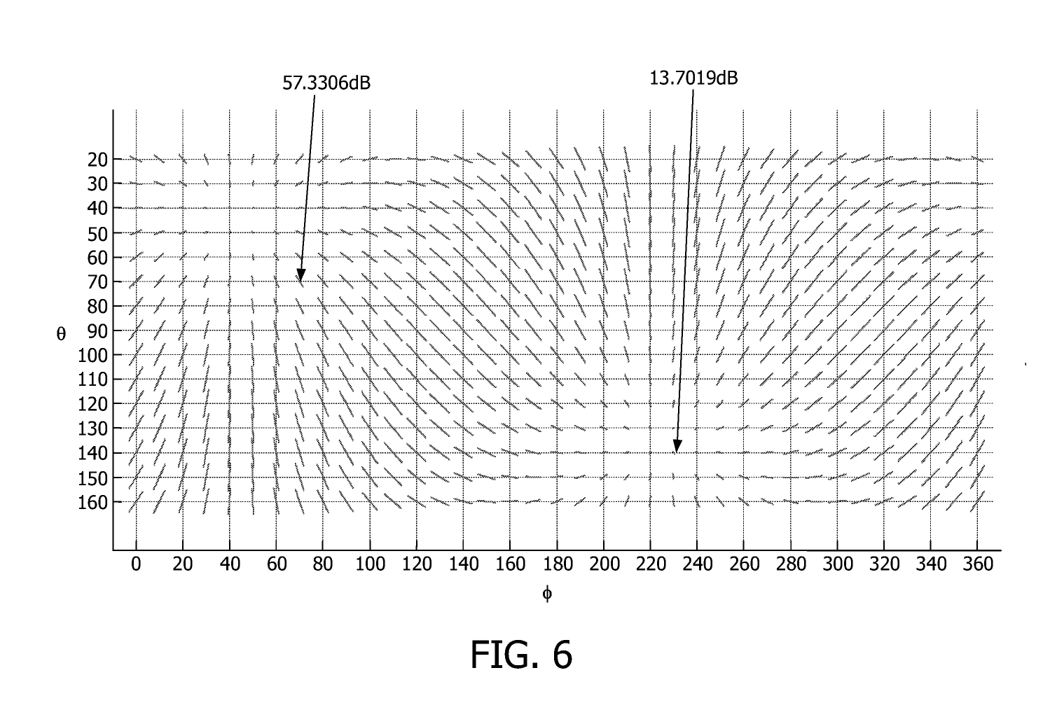

FIG. 6 illustrates the polarization pattern for the dipole antenna in several sample directions plotted in the two-dimension planar rectangular chart of the invention according to the above-mentioned method for polarization display of antenna, wherein the vertical axis for the two-dimension planar rectangular chart is axis θ and the horizontal axis is axis φ. Plotting of the polarization pattern can be done with help of a computer.

After obtaining the polarization pattern as shown in FIG. 6, it can be very easy for those skilled in the art to determine the dipole antenna is linearly polarized, because the polarization pattern for this dipole antenna in all radiation directions resembles line segments approximately. Furthermore, it can be seen from FIG. 6 that the line segments have small size in regions near the two points where (θ, φ) is (45°, 45°) and (135°, 230°), that is, near the radiation directions along the two ends of the dipole antenna. The line segments in other regions have large size, so it can be determined that the dipole antenna has weak radiation field intensity in the radiation directions along the two length ends of the dipole antenna and has strong radiation field intensity in other directions, which accords with the radiation characteristics of the antenna shown by the donut pattern of FIG. 5. From the positional relationship between each line segment and the coordinates axis shown in FIG. 6, the tilt angle of the linear polarization for the antenna in each radiation direction can be determined. FIG. 6 also shows two radiation directions with minimum AR value of 13.7019 dB and maximum AR value of 57.3308 dB. With reference to the AR values of the two radiation directions, the distribution of the AR values for the dipole antenna in all radiation directions can be estimated approximately.

It can be seen from the above description that the polarization pattern in the two-dimension planar rectangle chart shown in FIG. 6 may help technicians to get easily the polarization type, tilt angle of the polarization and AR value for the dipole antenna in each radiation direction.

II. Patch Antenna with Circular Polarization

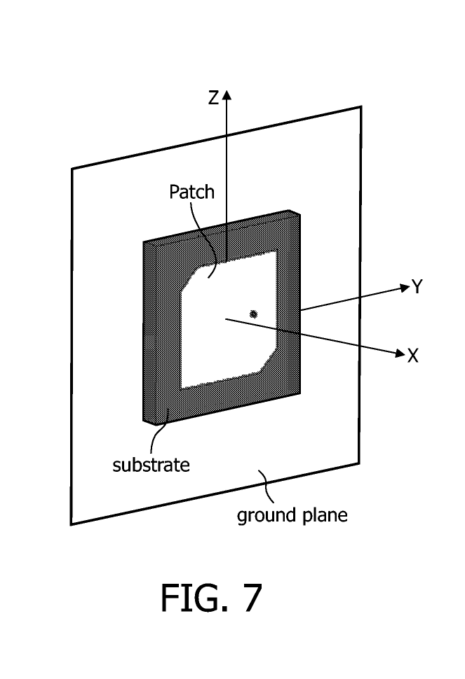

FIG. 7 shows a typical patch antenna with circular polarization, where the patch antenna is located within the Z-Y plane of the spherical coordinates system with its center at the origin of the coordinates system.

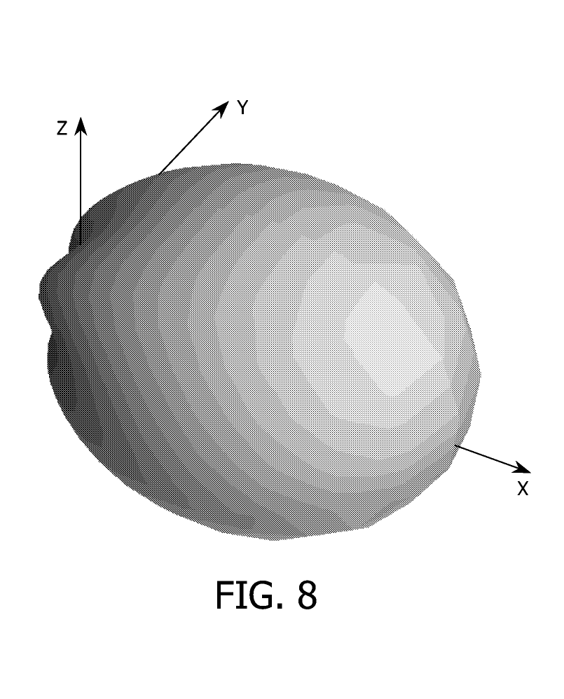

FIG. 8 illustrates the three-dimension radiation pattern of the patch antenna obtained by using an existing antenna simulation software. It can be seen from FIG. 8 that the patch antenna has stronger radiation field intensity in the radiation directions in front of the patch and has very weak radiation field intensity in the radiation directions behind the patch.

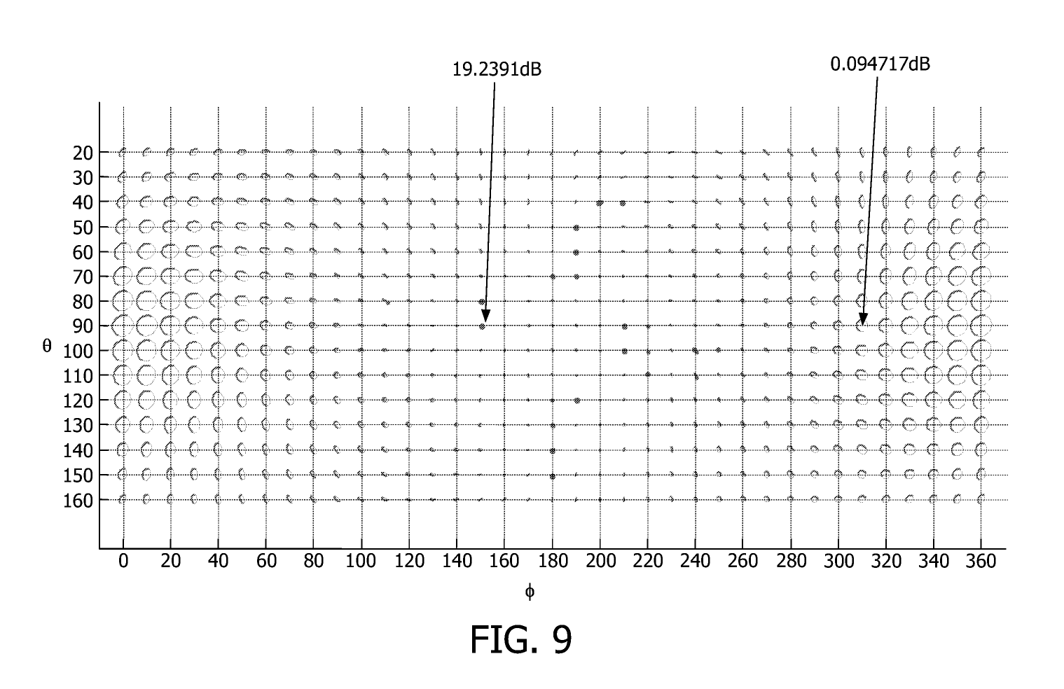

FIG. 9 illustrates the polarization pattern for the patch antenna in several sample directions plotted in the two-dimension planar rectangular chart according to the method for polarization display of antenna, where the vertical axis for the two-dimension planar rectangular chart is axis θ and the horizontal axis is axis φ. Plotting of the polarization pattern can be performed with help of a computer.

After the polarization pattern of FIG. 9 is obtained, it can be found that the patch antenna has near circular polarization pattern in each radiation direction, thereby technicians can determine that the patch antenna is circularly polarized. According to FIG. 9, it can be found that the circles have small size in the radiation directions behind the patch of the patch antenna, that is, the region near the point where (θ, φ) is (90°, 180°). The circles have large size in other regions, especially in radiation directions in front of the patch of the patch antenna. Based on this, it can be determined that the patch antenna has strong radiation field intensity in radiation directions in front of its patch and weak radiation field intensity in radiation directions behind its patch, which accords with the radiation characteristics of the antenna indicated in the three-dimension radiation pattern of FIG. 8. It can be seen from FIG. 9 that the trace for each circle changes from thick to thin gradually counterclockwise. It can thus be determined that the patch antenna has right-hand circular polarization in all radiation directions. FIG. 9 further illustrates two radiation directions with minimum AR value of 0.094717 dB and maximum AR value of 19.2891 dB. With reference to the AR values of the two radiation directions, the distribution of the AR value for the antenna in each radiation direction can be estimated approximately.

According to the above description, it can be seen that the polarization pattern in the two-dimension planar rectangular chart shown in FIG. 9 may help technicians to easily obtain the polarization type, polarization sense and AR value for the patch antenna in each radiation direction.

III. PIFA with a Complicated Polarization

Besides typical linearly and circularly polarized antennas, most antennas generally have complicated polarization characteristics.

FIG. 10 depicts the structure for a PIFA (Planar Inverted-F Antenna) with complicated polarization characteristics. As shown in FIG. 10, the PIFA has a plate of 20 mm×20 mm which is amounted at the center of a ground plane of 100 mm×100 mm. The vertical distance between the plate and the ground plane is 10 mm. The PIFA has a structure similar to the antenna model described by Huynh, M.-C.; Stutzman, W, in “Ground plane effects on planar inverted-F antenna (PIFA) performance”, Microwaves, Antennas and Propagation, IEE Proceedings-, Vol. 150, No. 4, 8 Aug. 2003, pp. 209-213.

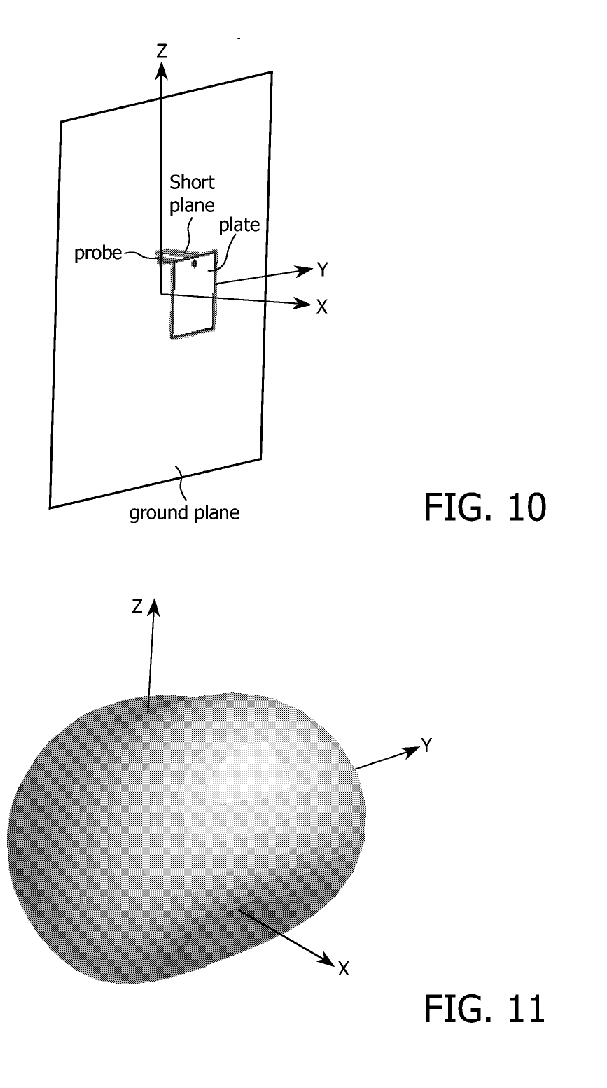

FIG. 11 illustrates the radiation pattern for the PIFA obtained by using an existing antenna simulation software. Distribution of the radiation field intensity for the PIFA in each radiation direction can be seen from FIG. 11.

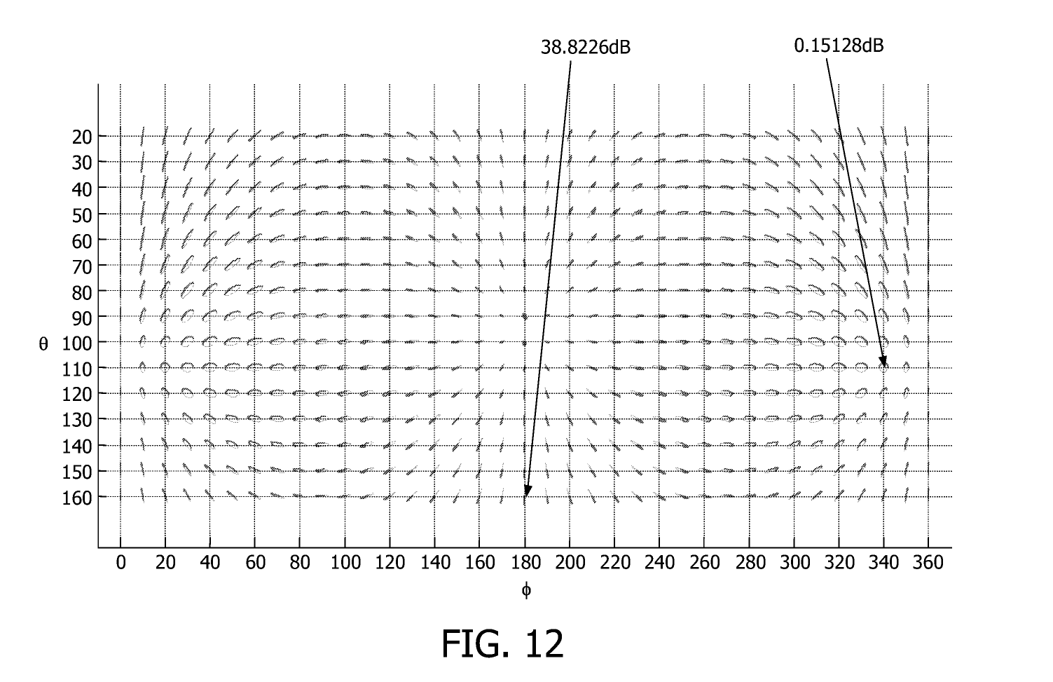

FIG. 12 illustrates the polarization pattern for the PIFA in multiple sample directions plotted in the two-dimension planar rectangular chart of the invention in accordance with the above-mentioned method for polarization display of antenna, where the vertical axis of the two-dimension rectangular chart is axis θ and the horizontal axis is φ. Plotting of the polarization pattern can be performed with help of a computer.

After the polarization pattern of FIG. 12 is obtained, it can be found that the polarization pattern of the PIFA includes near-circular, near-linear and elliptical patterns. Therefore, technicians can determine the PIFA has the complicated polarization characteristics. As shown in FIG. 12, the polarization pattern has small size in regions near directions where (θ, φ) is (90°, 180°) and (90°, 0°), and has large size in other directions. Based on this, it can be determined that the PIFA has weak radiation field intensity in the two radiation directions and strong radiation field intensity in other radiation directions, which accords with the radiation pattern in FIG. 11. As shown in FIG. 12, it can be seen that the polarization pattern of the PIFA is shown mainly as circular and elliptical in radiation directions of 10 degree<φ<120 degree and the trace for the circle and the ellipse changes from thick to thin gradually clockwise. The polarization pattern of the PIFA is also shown mainly as circular and elliptical in radiation directions of 240 degree<φ<350 degree and the trace for the circle and the ellipse changes from thick to thin gradually counterclockwise. Based on this, it can be determined that the PIFA has left-hand circular polarization and left-hand elliptical polarization, as well as right-hand circular polarization and right-hand elliptical polarization. According to the orientation of each ellipse shown in FIG. 12, the tilt angle for each elliptical polarization of the antenna can be determined. It can be seen from FIG. 12 that the polarization pattern for the PIFA is shown mainly as line segments in the radiation directions of 120 degree<φ<240 degree, thereby the tilt angle of each linear polarization for the antenna can be determined according to the location of each line segments with respect to the coordinates axis. FIG. 12 further illustrates two radiation directions with minimum AR value of 0.15 dB and maximum AR value of 38.82 dB. With reference to the AR values of the two radiation directions, the distribution of the AR value for the antenna in each radiation direction can be estimated approximately.

Based on the above description, it can be known that the polarization pattern in the two-dimension planar rectangular chart shown in FIG. 12 may help technicians to easily obtain the polarization type, polarization sense, tilt angle of the polarization and AR value for the PIFA in each radiation direction, that is, complete polarization information.

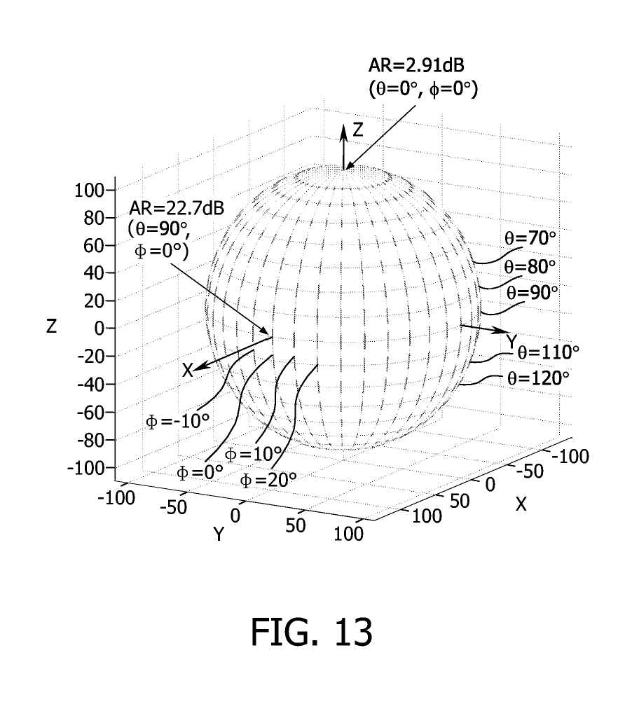

Detailed descriptions will be given below to the method for polarization display of antenna in form of spherical chart according to the invention in conjunction with FIGS. 13-15, by taking the above three well-known antenna structures as examples.

I. Dipole Antenna with the Linear Polarization

FIG. 13 illustrates the display results of all polarization characteristics of the dipole antenna on a spherical chart in accordance with another embodiment of the invention, wherein the dipole antenna is placed along the Z-axis of the spherical coordinates system, centered at the origin of the coordinates system.

After obtaining the polarization pattern of FIG. 13, technicians can determine the dipole antenna is a linearly polarized antenna, since the polarization patterns for the dipole antenna in all radiation directions are shown as line segments approximately. Because all lines are parallel with the longitude of the sphere, the radiation field of the dipole antenna is shown as vertically polarized. Further, it can be seen from FIG. 13 that the lines are longest near the equator of the sphere where θ is equal to 90 degree. Based on this, it can be determined that the dipole antenna has strongest radiation field intensity in radiation directions near the equator of the sphere, which is the feature of the donut-shaped radiation pattern of the antenna. FIG. 13 further illustrates the AR value of 2.91 dB at the pole of the sphere and the AR value of 22.7 dB at the crosspoint of the equator and the X-axis. With reference to the two AR values, distribution of the AR value for the dipole antenna in each radiation direction can be estimated approximately.

It can be seen from the above description that the polarization pattern in the spherical chart shown in FIG. 13 may help technicians to obtain all polarization information for the dipole antenna in each radiation direction easily.

II. Patch Antenna with the Circular Polarization

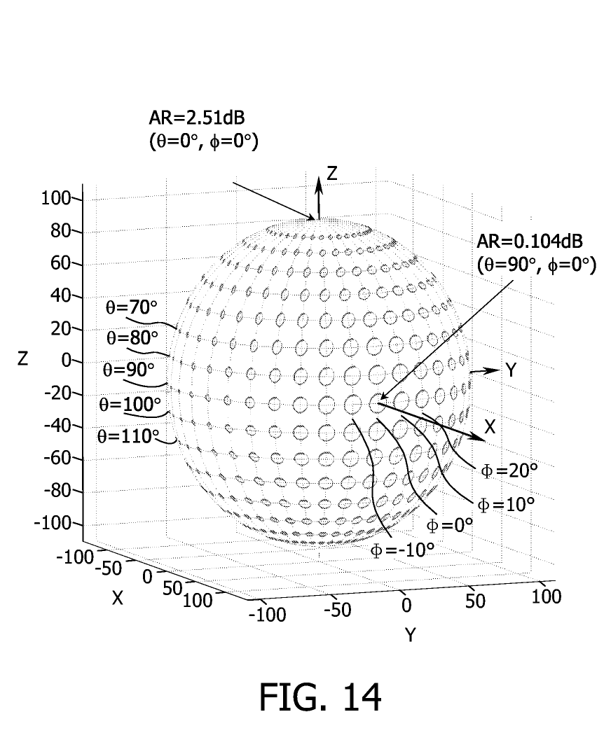

FIG. 14 illustrates the display results of all polarization characteristics of the patch antenna on the spherical chart in accordance with another embodiment of the invention, wherein the placement of the patch antenna and its three-dimensional pattern can be referred to FIG. 7 and FIG. 8 respectively.

After the polarization pattern of FIG. 14 is obtained, it can be found that the polarization pattern for the patch antenna is shown as circular in each radiation direction, thereby technicians can determine that the patch antenna is a circularly polarized antenna. In FIG. 14, it can be found that the trace for each circle changes from thick to thin gradually counterclockwise, and thus it can be determined that the patch antenna is a right-hand circularly polarized antenna. Furthermore, it can be seen from FIG. 14 that the circles have large size in the positive direction of the X-axis of the spherical coordinates system, and it can thus be determined that the patch antenna has strong radiation field intensity along the X-axis, which accords with the antenna characteristics indicated by the three-dimension radiation pattern in FIG. 8. FIG. 14 further illustrates the AR value of 0.104 dB at the pole of the sphere and the AR value of 2.51 dB near the X-axis on the equator. With reference to the two AR values, distribution of the AR value for the patch antenna in each radiation direction can be estimated approximately.

It can be seen from the above description that the polarization pattern in the spherical chart shown in FIG. 14 may help technicians to obtain all polarization information for the patch antenna in each radiation direction easily.

III. PIFA with the Complicated Polarization

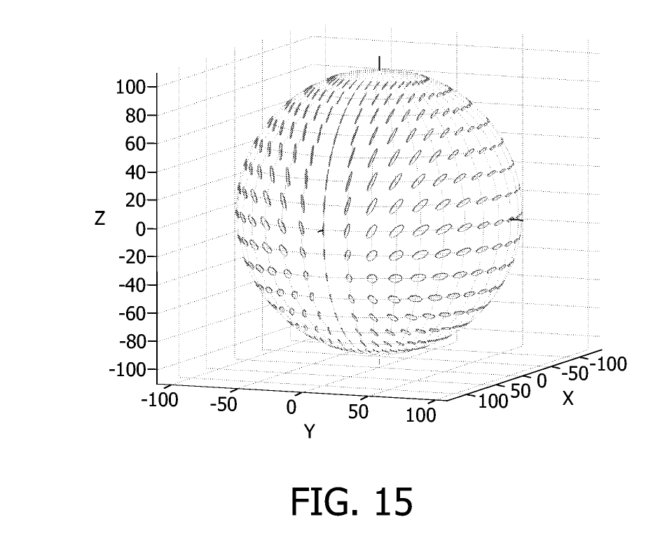

FIG. 15 illustrates the display result of all polarization characteristics of the PIFA on the spherical chart in accordance with another embodiment of the invention.

After the polarization pattern of FIG. 15 is obtained, it can be found that the polarization pattern of the PIFA includes near-circular, near-linear and elliptical patterns. Thereby, technicians can determine the PIFA has complicated polarization characteristics, rather than pure circular, linear or elliptical polarization. Furthermore, it's apparent from FIG. 15 that the PIFA antenna has vertically linear polarization with very high AR value in the radiation direction of the X-Z plane of the spherical coordinates system and the polarization of the PIFA antenna tends to be horizontally polarized in the radiation direction of the X-Z plane of the spherical coordinates system. Furthermore, it can be determined from FIG. 15 that the PIFA has strongest radiation field intensity in the radiation direction near the X-axis of the X-Z plane of the spherical coordinates system. FIG. 15 further illustrates the AR value of 24.59 dB at the pole of the sphere and the AR value of 28.29 dB near the X-axis and the AR value of 7.10 dB at the Y-axis. With reference to the three AR values, distribution of the AR value for the PIFA antenna in each radiation direction can be estimated approximately.

It can be seen from the above description that the polarization pattern in the spherical chart shown in FIG. 15 may help technicians to obtain all polarization information for the PIFA antenna in each radiation direction easily.

The above method for polarization display of antenna according to the invention can be implemented in software, or hardware, or in combination of both. It can be applied in print media and presswork, or alternatively, implemented and displayed on a computer by using software.

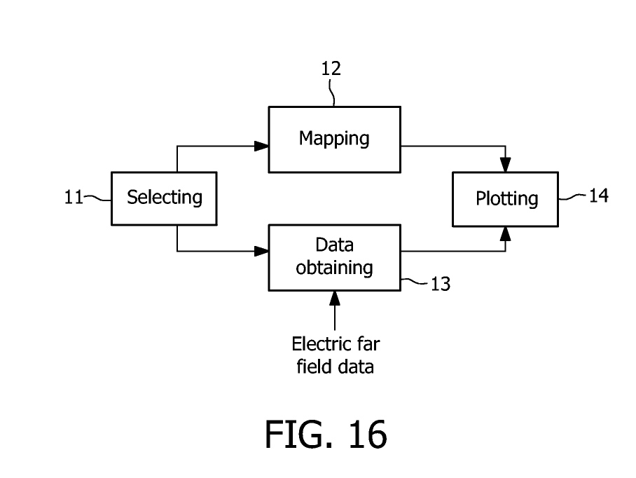

When the method for polarization display of antenna according to the invention is implemented in hardware, the corresponding functional modules are shown in FIG. 16. A selecting unit 11 is operable to select a plurality of sample directions from the antenna's radiation directions appropriately according to the display resolution requirement and report to a mapping unit 12 and a data obtaining unit 13. The mapping unit 12 maps the plurality of sample directions into the corresponding points in a two-dimension rectangular chart or a spherical chart. The data obtaining unit 13 obtains the electric far field data of the antenna in the plurality of corresponding sample directions by using an existing simulation software, and a plotting means 14 plots the polarization pattern of the antenna in the plurality of sample directions on the two-dimension rectangular chart or the spherical chart based on the electric far field data sent from the data obtaining unit 13.

From the detailed description to the embodiments of the invention taken in conjunction with accompanying drawings, it can be seen that the polarization pattern can provide the polarization type, polarization sense, tilt angle of the polarization and AR value for the antenna in each radiation direction by using the method for polarization display of antenna of the invention. Compared with prior arts, the method for polarization display of antenna of the invention can thus provide all polarization information of the antenna in each radiation direction.

Moreover, in the method for polarization display of antenna of the invention, a plurality of radiation directions are selected as sample directions from all radiation directions of the antenna, the electric far field data in each sample direction is obtained, each of the sample directions is mapped into its corresponding point in a two-dimension planar rectangular chart or a spherical chart, and the polarization pattern in each of the sample directions is plotted centered at the corresponding mapping point in the two-dimension planar rectangular chart or the spherical chart, based on the electric far field data in each sample direction. Compared with prior arts, the method for polarization display of antenna of the invention uses only one FIGURE, that is, only one two-dimension rectangular chart or spherical chart, to provide all polarization information for the antenna in each radiation direction.

It is to be understood by those skilled in the art that various improvement and modifications can be made to the method and apparatus for polarization display of antenna as disclosed in the present invention without departing from the basis of the present invention, the scope of which is to be defined by the attached claims herein.

1. A method for polarization display of antenna, comprising steps of:
(a) selecting a plurality of predetermined radiation directions from radiation directions of an antenna;
(b) mapping the plurality of predetermined radiation directions into a coordinates chart;
(c) obtaining corresponding radiation data for the antenna in the plurality of predetermined radiation directions; and
(d) plotting a polarization pattern of the antenna in the plurality of predetermined radiation directions on the coordinate chart, according to the corresponding radiation data.

2. The method for polarization display of antenna according to claim 1, further comprising step of:
if the antenna is elliptically or circularly polarized in one of the plurality of predetermined radiation directions, the corresponding trace of the polarization pattern in the radiation direction is plotted in such manner that it changes from thick to thin gradually along the rotation direction of the antenna's electric field vector in the radiation direction.

3. The method for polarization display of antenna according to claim 2, wherein, the coordinates chart is a planar coordinates chart and the plurality of predetermined radiation directions are mapped into a plurality of corresponding points on the planar coordinates chart.

4. The method for polarization display of antenna according to claim 2, wherein in step (b), the coordinates chart is a spherical coordinates chart and the plurality of predetermined radiation directions are mapped into a plurality of corresponding points on the spherical coordinate chart.

5. The method for polarization display of antenna according to claim 3, wherein in step (d), the polarization pattern is plotted by taking the corresponding points as centers.

6. The method for polarization display of antenna according to claim 1, wherein in step (c), the corresponding radiation data comprises module and phase of an electric field component.

7. An apparatus for polarization display of antenna, comprising:
a selecting means, for selecting a plurality of predetermined radiation directions from radiation directions of an antenna;
a mapping means, for mapping the plurality of predetermined radiation directions into a coordinates chart;
an obtaining means, for obtaining corresponding radiation data for the antenna in the plurality of predetermined radiation directions; and
a plotting means, for plotting a polarization pattern of the antenna in the plurality of predetermined radiation directions on the coordinates chart, according to the radiation data.

8. The apparatus for polarization display of antenna according to claim 7, wherein when the antenna is elliptically or circularly polarized in one of the plurality of predetermined radiation directions, the mapping means maps the corresponding trace of the polarization pattern in the radiation direction in such manner that it changes from thick to thin gradually along the rotation direction of the antenna's electric field vector in the radiation direction.

9. The apparatus for polarization display of antenna according to claim 8, wherein the coordinates chart is a planar coordinates chart and the mapping means maps the plurality of predetermined radiation directions into a plurality of corresponding points on the planar coordinates chart.

10. The apparatus for polarization display of antenna according to claim 8, wherein the coordinate chart is a spherical coordinates chart and the mapping means maps the plurality of predetermined radiation directions into a plurality of corresponding points on the spherical coordinates chart.

11. The apparatus for polarization display of antenna according to claim 9, wherein the plotting means plots the polarization pattern by taking the corresponding points as centers.

12. The apparatus for polarization display of antenna according to claim 7, wherein the corresponding radiation data comprises module and phase of an electric field component.
